(19) United States
(12) Patent Application Publication
(10) Pub. No.: US 2006/0033080 A1
(43) Pub. Date: Feb. 16, 2006

(54) Mixed solution for a display device and method for fabricating a display device by using the same

(75) Inventors: Koretomo Harada, Tokyo (JP); Shinju Otani, Yokohama-shi (JP); Kazuhiro Monzen, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: OPTREX Corporation, Tokyo (JP)

(21) Appl. No.: 11/198,147

(22) Filed: Aug. 8, 2005

(30) Foreign Application Priority Data
Aug. 9, 2004 (JP) 2004-232781

(51) Int. Cl. B05D 5/12; C09K 11/06

(52) U.S. Cl. 252/301.16; 427/66

(57) ABSTRACT

One mode of the fabricating method according to the present invention comprises the steps of spraying a solution in which a solute forming a least one portion of an organic layer is dissolved; and drying the substrate to evaporate the solvent contained in the sprayed solution; wherein the solution comprises a first solvent capable of dissolving the solute by 1 mass % or above and a volatile solvent capable of completely volatilizing before the sprayed solution has been arrived on the substrate.

### BACKGROUND OF THE INVENTION

The present invention relates to a mixed solution for a display device and a method for fabricating a display device by using the same.

For recent years, research and development has been actively conducted on organic EL display devices using an organic EL panel. Organic EL display devices are expected to be the next generation of display devices because of having a wider viewing angle range and faster response than liquid crystal display devices and because of an organic substance having a wide variety of light emission properties. An organic EL panel used in organic EL display devices has anodes disposed on a substrate, and an organic light-emitting layer formed on the substrate, the organic light emitting layer comprising organic multi-layer thin films. The organic EL panel is configured to have cathodes disposed on the organic multi-layer thin films so as to confront the anodes disposed on the substrate. The organic EL panel is a current-driven display panel, which emits light by itself when a current is supplied to the organic multi-layer thin films disposed between an anode and a cathode. Hereinbelow, the organic multi-layer thin films thus laminated will be called an organic thin film. A position where an anode, plural organic thin films and a cathode are overlapped with one another serves as a display pixel.

When organic compounds are laminated on electrodes disposed on a substrate, organic materials are vacuum-deposited to form organic thin films in some cases. In a case of vapor-depositing the organic materials, when an electrode as a foundation layer for the organic thin films has a foreign matter adhering on, or a projection or a recess formed on a surface thereof, an organic thin film is not formed in a desired state because of being adversely affected by the presence of such a foreign matter, a projection or a recess in some cases.

As a method for solving this problem, there has been known a technique wherein respective organic materials for forming the respective organic thin films are dispersed or dissolved in respective liquids, and the respective organic materials are applied as respective solutions to cover such a foreign matter, a projection, a recess or the like to dispose the organic thin films in a desired state (a wet application method, hereinbelow, referred as to the application method). For example, JP-A-2001-351779 discloses in paragraphs 0012 to 0017, and FIGS. 1 and 2 that at least one of organic thin films is formed by the application method.

Examples of the application method are an offset printing method, a relief printing method and a mask spray method. In the offset printing method and the relief printing method, a thin film, which comprises a solution containing an organic material dispersed or dissolved in a solvent, is formed only in certain areas. In the mask spray method, e.g., a glass mask or a metal mask, which has apertural areas formed therein so as to conform to desired areas, is positioned, and each of the solutions with an organic material dispersed or dissolved therein is sprayed. In the latter case, each of the solutions is atomized by dispersing each of the solutions in a gaseous medium, such as nitrogen, or by using a two-fluid nozzle or the like.

In organic EL display devices, partition walls (hereinbelow, referred as to the separators) are formed so that cathode wires disposed on organic thin films are disposed so as to be separated from one another. Such arrangement is disclosed in, e.g., JP-A-2001-315779 (paragraphs 0012 to 00147, and FIG. 1 and FIG. 2). FIG. 7 is a cross-sectional view showing an example of the separators disclosed in JP-A-2001-315779. The separators 100 are disposed after cathode wires 101 are disposed on a substrate 111. The separators 100 are formed so as to have their cross-sectional width increasing as the distance from the substrate 111 increases, for example. That sort of separator structure is called an inverted tapered structure or an overhang structure.

By providing the separators 100 with such an inverted tapered structure, it is possible to more reliably separate the cathode wires. When respective organic thin films (a hole injection and transport layer 102, a light emitting layer 103 and an electron injection and transport layer 104) are formed by the application method or the like in such state that the separators 100 have been formed, the respective organic thin films are separated by the separators 100, and consequently an organic light emitting layer comprising the organic thin film is formed in the gap between adjacent separators 100. After that, cathode wires 105 are formed by a vapor deposition method or the like. Since the cathode wires 105 are also separated by the separators 100, the cathode wires 105 are formed, being patterned.

In some cases, an insulating film having apertural areas is formed on the anode wires to determine positions serving as display pixels by the positions of the apertural areas. FIGS. 8(a) and (b) are schematic views showing an example wherein an insulating film having apertural areas is formed in the structure disclosed in JP-A-2001-351779 (paragraphs 0012 to 0017, and FIGS. 1 and 2). FIG. 8(a) is a schematic view showing the appearance of a substrate, which is observed from the side of the substrate with the electrodes formed thereon. FIG. 8(b) is a cross-sectional view taken along the line A-A′ of FIG. 8(a). FIG. 8(a) also shows components, which are hidden by cathode wires and the like formed as upper layers.

In the example shown in FIGS. 8(a) and (b), anode wires 101 and cathode connection wires 121 to be connected to cathode wires 105 are first formed on a substrate 111. Subsequently, an insulating film 122 having apertural areas 123 is formed. The apertural areas 123 are formed at positions where the anode wires 101 and the cathode wires 105 are supposed to intersect each other. Then, solutions containing different organic materials are applied or vapor-deposited to form organic thin films 124.

Although plural films are formed as the organic thin films, the organic thin films are collectively shown by a single organic thin layer 124 in FIG. 8(b). The respective solutions are prepared so that the concentrations and the like of the organic material are adjusted so as to form the organic thin films in desired thicknesses in regions to form the organic thin films. After forming the organic thin layer 124, the cathode wires 105 are vapor-deposited on the top of the organic thin layer. Separators 100 serve as separating the organic thin layer 124 or the cathode wires 105 into parts, thereby to form the organic thin layer 124 in the gap between adjacent separators or to form the cathode wires 105 in a pattern.

In some cases, an organic thin film comprising, e.g., a polymer is formed on the cathode wires 105 in order to protect the organic EL panel after deposition of the cathode wires 105. Such an organic thin film (not shown) may be also applied by the application method or the like. On the side of the substrate 111 with the electrodes and the like formed thereon, a second substrate (not shown) is disposed in a confronting way. A seal (not shown) is applied on an outer peripheral portion of a region of the second substrate, which is opposed to the organic EL panel on the substrate 111. The substrate 111 and the second substrate are bonded together by the seal. The organic EL panel is protected from exposure to moisture or oxygen because of being encapsulated by both substrates and the seal.

In the method stated above, the organic material for forming an organic thin film is a solute, and the solution is applied with the solute being dispersed or dissolved in a solvent. After the solution is applied, the solvent is evaporated by a drying and concentration process. Thus, the organic material is formed as the organic thin film. Organic EL panels have a light emitting property varied according to an organic material included therein, i.e., the material forming a solute. As the material forming a solute, a material having a desired light emitting property is used.

As stated above, what is important for forming the organic thin layer 124 by the application method is the material forming a solution. A wide variety of organic materials, which are used for forming the organic thin layer, have been developed according to light emitting properties (see, e.g., JP-A-2001-160493 and JP-A-2002-151272).

### DISCLOSURE OF THE INVENTION

When such a solution is wet-applied by, e.g., a spray applicator, it is difficult to apply a solution having a high concentration and a high viscosity. For this reason, a solute is applied, being dissolved in a certain amount or more of good solvent. However, when a solute is applied, being dissolved in a solvent, the viscosity is lowered. Accordingly, when an organic material solution having a low viscosity is applied after formation of the separators 100, there is caused a problem that the applied solution spreads along the separators 100. For example, in the case shown in FIGS. 8(a) and (b), the solution spreads along each portion where a lateral surface of the separators 100 and the insulating film 122 intersect each other. This is because a phenomenon similar to the capillary phenomenon is generated by spaces formed in the vicinity of each portion where a lateral surface of the separators 100 and a surface of the insulating film 122 intersect each other. In particular, when the separators 100 are formed so as to have an inverted tapered structure in order to reliably separate the cathode wires 105 and the like into parts, the solution is more apt to spread since the spaces formed in the vicinity of each portion where a lateral surface of the separators 100 and a surface of the insulating film 122 intersect each other, are narrower.

When a solution has a low viscosity, it has been impossible to form the organic material uniformly since the applied solution spreads as stated above. On the other hand, even when an attempt is made to use a solution having a high viscosity, it is impossible to dissolve a certain amount or more of solute in some cases. Additionally, it is impossible to uniformly apply a solution having a high viscosity by some of applicators. Further, when the temperature of the substrate is increased in the drying and concentration process, the solution is apt to spread since the viscosity of the solution is lowered.

In the conventional organic EL display devices, non-uniformity in light emission is caused by non-uniformity in a film thickness, which is created when the liquid material for forming an organic film flows out of an active area as stated above. This has caused a problem that display quality is degraded.

The present invention is proposed in consideration of the problem stated above. It is an object of the present invention to provide a mixed solution for a display device and a method for fabricating a display device by using the same, which are capable of uniformly applying an organic material and decreasing the occurrence of degradation in display quality caused by non-uniformity in a film thickness.

The mixed solution according to a first aspect of the present invention is a mixed solution for forming an organic layer for a display device, comprising a solute to form at least one portion of the organic layer; a first solvent capable of dissolving the solute by 1 mass % or above; and a second solvent having a higher viscosity than the first solvent. By using this mixed solution, it is possible to uniformly the organic layer.

In the mixed solution according to a second aspect of the present invention, the second solvent has a viscosity of 10 or more times the first solvent in the mixed solution defined in the first aspect. By using this mixed solution, it is possible to easily obtain a solution having a viscosity appropriate for application.

In the mixed solution according to a third aspect of the present invention, the second solvent has a volume of from ⅔ to 7 times the first solvent in the mixed solution defined in the first aspect. By using this mixed solution, it is possible to uniformly the organic layer.

The mixed solution according to a fourth aspect of the present invention is a mixed solution for forming an organic layer for a display device, comprising a solute to form at least one portion of an organic layer; a first solvent capable of dissolving the solute by 1 mass % or above; and a volatile solvent capable of completely volatilizing after spraying of the mixed solution toward a substrate for a display device and before arrival on the substrate. By using this mixed solution, it is possible to uniformly the organic layer.

In the mixed solution according to a fifth aspect of the present invention, the volatile solvent has a boiling point of 120° C. or below or a vapor pressure of 400 Pa or above at 25° C. in the mixed solution defined in the fourth aspect. By using this mixed solution, it is possible to uniformly the organic layer.

The mixed solution according to a sixth aspect of the present invention further comprises a second solution having a higher viscosity than the first solvent and the volatile solvent in the mixed solution defined in the fourth aspect. By using this mixed solution, it is possible to more uniformly the organic layer.

The method for fabricating a display device, according to a seventh aspect of the present invention is a method for fabricating a display device by wet-applying a solution, in which a solute forming a least one portion of an organic layer for the display device is dissolved; comprising steps of applying the solution to a substrate; and drying the substrate and evaporating a solvent contained in the applied solution; wherein the solution comprises a first solvent capable of dissolving the solute by 1 mass % or above; and a second solvent having a higher viscosity than the first solvent.

By using this method, it is possible to uniformly the organic layer.

In the method according to an eighth aspect of the present invention, the second solvent has a viscosity of 10 or more times the first solvent in the method defined in the seventh aspect. By using this method, it is possible to easily obtain a solution having a viscosity appropriate for application.

In the method according to a ninth aspect of the present invention, the second solvent has a volume of from ⅔ to 7 times the first solvent in the method defined in the seventh aspect. By using this method, it is possible to uniformly the organic layer.

The method according to a tenth aspect of the present invention is a method for fabricating a display device by spraying a solution, a solute forming a least one portion of an organic layer for the display device being dissolved in the solution; comprising the steps of spraying the solution toward a substrate; and drying the substrate to evaporate a solvent contained in the sprayed solution; wherein the applied solution comprises a first solvent capable of dissolving the solute by 1 mass % or above; and a volatile solvent capable of completely volatilizing before the sprayed solution has been arrived on the substrate. By using this method, it is possible to uniformly the organic layer.

In the method according to an eleventh aspect of the present invention, the volatile solvent has a boiling point of 120° C. or below or a vapor pressure of 400 Pa or above at 25° C. in the method defined in the tenth aspect. By using this method, it is possible to more uniformly the organic layer.

The method according to a twelfth aspect of the present invention further comprises spraying a second-solution having a higher viscosity than the first solvent and the volatile solvent in the spaying step in the method defined in the tenth aspect. By using this method, it is possible to more uniformly the organic layer.

The method according to a thirteenth aspect of the present invention further comprises of, before the spraying step, a step for confirming that the volatile solvent does not arrive on a confirmation substrate after only the volatile solvent is sprayed toward the confirmation substrate; and spraying the solution under the same conditions as the confirmation step in the method defined in the tenth aspect. By using this method, it is possible to easily check that the volatile solvent does not arrive on the substrate.

The method according to a fourteenth aspect of the present invention further comprises of, before the spraying step, a step for spraying only the volatile solvent while changing a distance between a spray nozzle for spraying the solution and the confirmation substrate; determining whether the volatile solvent sprayed toward the confirmation substrate arrives on the confirmation substrate or not, and spraying the solution toward the substrate in the spraying step with a length between the spray nozzle and the substrate being set at at least a value that is determined to prevent the volatile solute from arriving on the confirmation substrate in the method defined in the tenth aspect. By using this method, it is possible to find the distance between the substrate and the spray nozzle that can prevent the volatile solvent from arriving on the substrate.

In accordance with the present invention, it is possible to provide a mixed solution and a method for fabricating a display device by using the same, which are capable of uniformly applying an organic material.

### BRIEF DESCRIPTION OF THE DRAWINGS

FIG. 1 is a top plan view showing a schematic structure of a panel substrate of an organic EL display device according to the present invention;

FIG. 2 is a cross-sectional view showing an example of the structure of the organic EL light emitting layer according to the present invention;

FIG. 3 is a schematic view showing the structure of a spray applicator used for fabrication of an organic EL display device according to the present invention;

FIG. 4 is a top plan view of a mask along with a scanning path of the spray nozzle in the spray applicator shown in FIG. 3;

FIG. 5 is a flowchart showing an example of the fabrication process for an organic EL display device according to the present invention;

FIG. 6 is a cross-sectional view schematically showing an example of the structure of an organic EL display panel according to the present invention;

FIG. 7 is a cross-sectional view showing the structure of the panel substrate of a conventional organic EL display device; and

FIGS. 8(a) and (b) are views showing the structure of the panel substrate of a conventional organic EL display device.

### DETAILED DESCRIPTION OF THE INVENTION

Now, an embodiment, to which the present invention is applicable, will be described. The following description is provided for explanation of embodiments of the present invention, and the present invention is not limited to the embodiments described below.

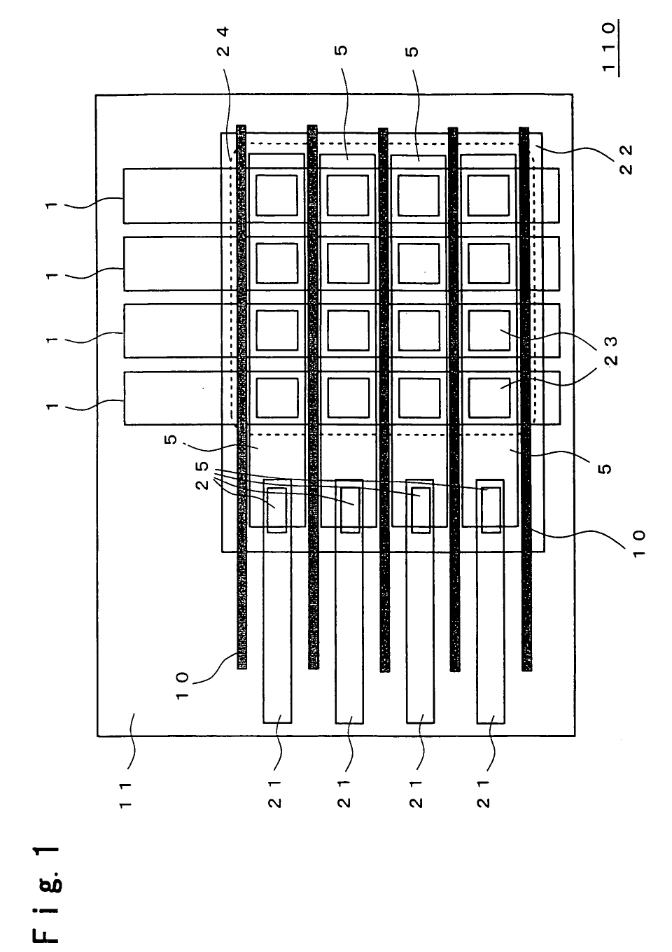

A panel substrate, on which the organic EL light emitting panel of the organic EL display device according to an embodiment of the present invention is disposed, will be described, referring to FIG. 1. FIG. 1 is a plan view showing the structure of the panel substrate 110 of the organic EL display device. Reference numeral 1 designates an anode wire, reference numeral 5 designates a cathode wire, reference numeral 10 designated a separator, reference numeral 11 designates the substrate, reference numeral 21 designates a cathode connection wire, reference numeral 22 designates an insulating film, reference numeral 23 designates an apertural area, reference numeral 24 designates an active area indicated by a dotted line, and reference numeral 25 designates a contact hole.

The substrate 11 has plural anode wires 1 and is cathode connection wires 21 for connection with cathode wires formed thereon so as to have contact with a surface of the substrate 11. The plural anode wires 1 are formed so as to be parallel with one another. The cathode connection wires 21 are formed in a number corresponding to the number of the cathode wires 5 and extend so as to be perpendicular to the anode wires 1. The anode wires 1 and the cathode connection wires 21 are formed from a transparent conductive layer, such as an ITO film. The substrate with the anode wires 1 and the cathode connection wires 21 formed thereon has the insulating film 22 formed thereon. The insulating film 22 has a film thickness of, e.g., 0.7 μm. The insulating film 22 has apertural areas 23 formed therein at each position, where an anode wire 1 and a cathode wire 5 intersects each other (i.e., at positions where display pixels are formed). The active are 24 comprises plural display pixels, and each of the display pixels controls the light emission amount of its organic light emission layer according to a driving signal from a driving circuit (not shown), whereby the active area 24 displays an image.

The insulating film 22 has an organic light emitting layer and the cathode wires 5 laminated thereon in this order as upper layers, the organic light emitting layer comprising plural organic thin films (organic multi-layer thin films). The organic light emitting layer is configured to be sandwiched between a cathode wire 5 and an anode wire 1. In FIG. 1, such an organic light emitting layer is not shown. Before forming the organic light emitting layer, partition walls for separating adjacent cathode wires 5 (hereinbelow, referred to as the separators 10) are formed. The separators 10 are formed in a desired pattern before the cathode wires 5 are formed by vapor deposition or the like. For example, the plural separators, which are perpendicular to the anode wires 1, are formed on the anode wires 1 in order that the plural cathode wires 5 are formed so as to be perpendicular to the anode wires 1 as shown in FIG. 1. It is preferred that the separators 10 have an inverted structure. In other words, it is preferred that each of the separators have its cross-sectional width increasing as the distance from the substrate 11 increases. By this arrangement, the lateral walls and the rising portions of the separators 10 can serve as shades against vapor deposition to separate the cathode wires 5 from one another. The separators 10 may be formed so as to have a height of 3.4 μm and a width of 10 μm for example.

At least one of the organic thin films forming the organic light emitting layer is formed by applying a liquid organic material for the relevant light emitting layer as an organic material solution. Application of such an organic material solution will be described in detail later.

The organic thin film material thus applied is condensed, dried and cured to form a desired organic thin film. Thus, the organic thin film is made in an uniform film thickness in the active area 24. In a case wherein an organic thin layer has a multi-layered structure, a vapor deposition method may be utilized in addition to the application method. In other words, in a case wherein an organic thin layer comprises multi-layers, as long as at least one film is formed by the application method, another film may be formed by the vapor deposition method. In this case, after at least one film is applied by the application method, the applied film is condensed, dried and cured before the applied film has another film formed thereon. The organic thin film is separated into parts by the respective separators 10.

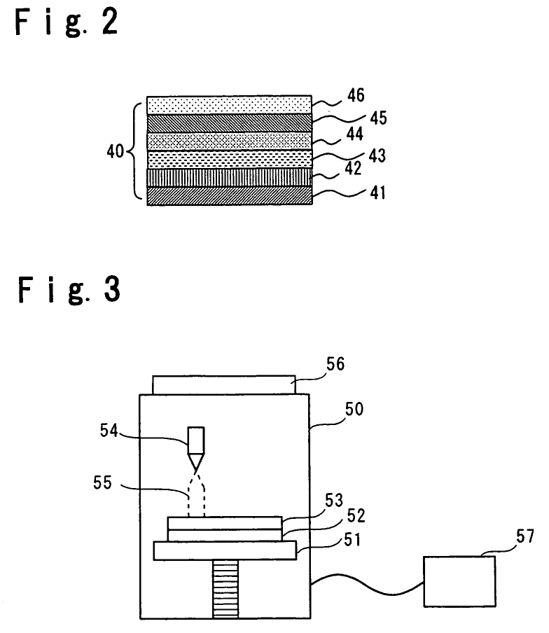

The organic thin layer is formed so as to have a multi-layered structure shown in FIG. 2, for example. FIG. 2 is a cross-sectional view schematically showing an example of the structure of the organic thin layer 40. The organic thin layer 40 includes a polymer buffer layer 41, a hole injection layer 42, a hole transport layer 43, a light emitting layer 44, an electron transport layer 45, and an electron injection layer 46 in this order from the bottom. In other words, at an apertural area 23, the polymer buffer layer 41 is brought into contact with an anode wire 1, and the electron injection layer 46 is brought into contact with a cathode wire 5. In this embodiment, the polymer buffer layer 41 is formed by the application method, and the hole injection layer 42, the hole transport layer 43, the light emitting layer 44, the electron transport layer 45 and the electron injection layer 46 are formed by the vapor deposition method. By the polymer buffer layer 41, it is possible to avoid short-circuit and to prevent a driving voltage from lowering. The materials for forming the organic thin layer 40 will be described later. It should be noted that the organic thin layer 40 is not limited to have such a structure, and that at least one of the organic thin films is formed by the application method.

After the separators 10 are formed, a metal material and the like for the cathode wires 5 are vapor-deposited from above the organic thin layer. By the separators 10 having an inverted structure, it is possible to the plural cathode wires 5 in a separated cathode pattern. The cathode wires 5 separated by the separators 10 are formed so as to be perpendicular to the anode wires 1. The organic light emitting layer is positioned between a cathode wire 5 and an anode wire 1 at the intersection of the cathode wire 5 and the anode wire 1.

The insulating film 22 has the contact holes 25 formed therein outside the active region 24 to connect the cathode connection wires 21 to the cathode wires 5. Each of the contact holes 25 is formed at a position where a cathode wire 5 and a cathode connection wire 21 overlap each other. By this arrangement, a current can be flowed in the organic thin layer sandwiched by the anode wire 1 and the cathode wire 5 at each of the apertural portions 23, thereby causing the organic light emitting layer to emit light.

Now, a spray applicator for spraying the organic material stated above will be explained, referring to FIG. 3. FIG. 3 is a schematic view showing the structure of the spray applicator. Reference numeral 50 designates the spray applicator, reference numeral 51 designates a stage, reference numeral 52 designates a substrate, reference numeral 53 designates a mask, reference numeral 54 designates a spray nozzle, reference numeral 55 designates an applied solution, reference numeral 56 designates a filter, and reference numeral 57 designates a controller.

The spray applicator 50 includes the stage 51 for carrying the substrate 52 thereon, the spray nozzle 54 for applying the applied solution 55 to the substrate 52, and the controller 54 for controlling the spray nozzle 54. The substrate 52 used in this embodiment has a rectangular shape of 300 mm×400 mm. The mask 53 is put on the substrate 52 carried on the stage 51. The mask 53 may be put on the substrate 52 directly or with a gap. The mask 53 is a metal plate made of, e.g., aluminum, and has substantially the same dimensions as the substrate 52. The mask 53 has apertural areas formed therein so as to correspond to the active area 24 indicated by the dotted line in FIG. 1. The substrate 52 is a substrate, on which the organic EL panel shown in FIG. 1 is formed. The mask 53 has the plural apertural areas formed therein so as to form at plural positions the organic EL display panel shown in FIG. 1 on the substrate 52 as a single substrate.

The spray nozzle 54 is disposed above the stage 51 so as to be movable in a horizontal direction. The spray nozzle 54 is a fluid nozzle, which is supplied with a gas, such as nitrogen, having an applied solution dispersed therein, and atomizes and sprays the applied solution. Accordingly, the applied solution is sprayed in a downward direction from the leading edge of the spray nozzle 54. Thus, the solution 55 is applied onto the substrate 52 from the spray nozzle 54 through the mask 53. In this embodiment, an organic material for forming at the plural positions the organic EL panel on the substrate 52 is applied under the condition that nitrogen gas is supplied to the spray nozzle 54 at 0.5×10⁻³ m³/min (=0.51/min) and that the flow rate of the applied solution (the flow rate of the applied liquid) is set at 0.9×10⁻⁶ m³/min (=0.9 ml/min).

The controller 57 comprises an information processor, such as a personal computer (PC), and controls the spray nozzle 54 and the stage 51. Specifically, the controller controls the scan speed, the scanning pitch and the flow rate of the applied liquid of the spray nozzle 54, the distance between the spray nozzle 54 and the substrate 52 and the like. The spray nozzle 54 moves in the horizontal direction to apply the solution 55 on the entire surface of the substrate 52 in accordance with a signal from the controller 57. The controller 57 can vertically move the spray nozzle 54 or the stage 51 to control the distance between the spray nozzle 54 and the substrate 52. In this embodiment, the distance between the leading edge of the spray nozzle 54 and the surface of the substrate 52 confronting the spray nozzle is set at 80 mm.

The filter 56 comprises an air filter, such as a HEPA filter. Air can be supplied into the spray applicator through the filter 56 to keep a clean space in the spray applicator 50. By this arrangement, it is possible to prevent a foreign substance from adhering to the substrate 52 during application and to improve yield. The application by the spray is normally performed in such a state that the substrate is at room temperature.

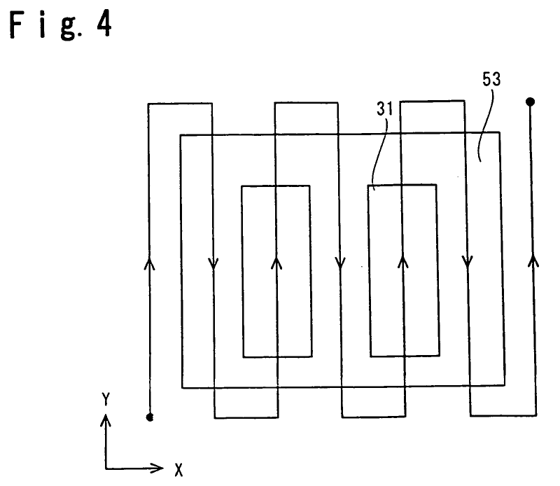

Next, the scanning process of the spray nozzle 54 will be described, referring to FIG. 4. FIG. 4 is a top plan view of the mask 53, which also shows the scanning path of the spray nozzle 54. FIG. 4 shows an example wherein the mask 53 has two apertural areas 31 formed therein. The arrows in FIG. 4 indicate a trace, along which the leading edge of the spray nozzle 54 follows.

In this embodiment, the spray nozzle 54 is subjected to raster scanning to apply the solution on the entire surface of the substrate as shown in FIG. 4. In other words, the spray nozzle 54 is moved along the arrow from an outside area to the opposite outside area of the substrate 52. Specifically, the spray nozzle 54 is moved in the direction indicated by Y so as to pass across the substrate 52 from an outside area of the mask 53. When the spray nozzle 54 has moved to the opposite end of the mask 53, the spray nozzle 54 is shifted by a certain distance (pitch) in the direction indicated by X. After the spray nozzle 54 is moved from end to end of the mask 53 in the Y direction again, the spray nozzle is shifted by the same distance (pitch) as the previous one in the X direction. Thus, the spray nozzle 54 reciprocates on the substrate in the Y direction since the movement in the Y direction at that time is opposite to the previous movement. The solution is applied on the entire surface of the substrate by repeating such movement until the spray nozzle 54 has passed across the substrate in the X direction.

The solution thus applied adheres to the substrate 52, passing through the apertural areas 31 of the mask 53. The apertural areas 31 correspond to the active area 24 shown in FIG. 1, and the applied solution adheres only to certain regions. In other words, the mask 53 with the apertural areas 31 formed therein is utilized to prevent the applied solution from adhering to connection terminals and the contact holes 25 shown in FIG. 1. In the example shown in FIG. 4, the mask 53 has the two apertural areas 31 formed therein. The number of the apertural areas 31 corresponds to the number of organic EL display panels to be formed on the substrate 52. In other words, the organic EL display panel shown in FIG. 1 is formed at two positions on the single substrate 52. It should be noted that the number of the apertural areas 31 is not limited to two.

In order to uniformly apply a solution to the entire substrate, it is preferred that the spray nozzle 54 be moved at a constant speed and with a constant flow rate of the applied liquid. In order that the edges of the substrate and a central portion of the substrate have substantially the same application amount as each other, it is preferred that the spray nozzle 54 be moved to outside the substrate 52. In other words, the spray nozzle 54 is preferably moved beyond the outer edges of the substrate 52. This results in a solution being uniformly applied to the entire substrate 52.

The scan speed of the spray nozzle 54 is 300 mm per sec for example. The application range of the spray nozzle 54 on the substrate surface is a circle having a diameter of 30 mm. In other words, when the spray nozzle 54 sprays the solution 55, being fixed, the solution is applied in a circular region having a diameter of 30 mm on the substrate surface. This means that when the spray nozzle 54 is moved in the Y direction, the solution is applied in a width of 30 mm in the X direction.

When scanning the spray nozzle 54, it is preferred that the solution be applied so that application ranges partly overlap each other. In other words, it is preferred that the distance (pitch) for shifting the spray nozzle in the X direction be not longer than 30 mm, which is the diameter of each of the application ranges. In this embodiment, the spray nozzle has a shift pitch of 12 mm in the X direction.

Specifically, when the substrate 52 has dimensions of 300 mm×400 mm, the spray nozzle 54 is moved by 300 mm or above in the Y direction so as to pass across the substrate 52. After the spray nozzle 54 is shifted by 12 mm in the X direction, the spray nozzle is moved by 300 mm or above in the Y direction again. In this time, the movement of the spray nozzle in the Y direction is opposite to the previous movement. Additionally, the spray nozzle 54 is shifted by 12 mm in the X direction, having the same shifting direction as the previous shifting direction. By repeating such shifting, the spray nozzle is moved by 400 mm or above in the X direction. Thus, the spray nozzle 54 can scan in a zigzag pattern as shown in FIG. 4, uniformly applying the solution in a target surface.

Now, the applied solution will be described. The present invention uses a plurality of solvents in order to prevent the applied solution from flowing out along a separator after application. A solute to be used in the present invention may comprise, e.g., one disclosed in JP-A-2001-160493 or JP-A-2002-151272. This solute forms a material for the polymer buffer layer 41.

In the present invention, a polymer material of 1 weight % is dissolved in a good solvent comprising cyclohexanol and 1,3-dimethyl-2-imidazolidinone mixed at a volume ratio of 3:2, and 2-methyl-1-propanol is added thereto in such a volume of two or five times the good solvent. In other words, cyclohexanol, 1,3-dimethyl-2-imidazolidinone, and 2-methyl-1-propanol are mixed at a volume ratio of from 6:4:20 to 6:4:50, and the mixture is used as the solvent. It is particularly preferred to use a solvent comprising cyclohexanol, 1,3-dimethyl-2-imidazolidinone, and 2-methyl-1-propanol mixed at a volume ratio of 6:4:30.

Cyclohexanol has a viscosity of 5.454×10⁻² Pa·s (=54.54 cP) at 25° C. 1,3-dimethyl-2-imidazolidinone has a viscosity of 2.06×10⁻³ Pa·s (=2.06 cP) at 25° C. 2-methyl-1-propanol has a viscosity of 3.42×10⁻³ Pa·s (=3.42 cP) at 25° C. The solution, wherein the solute was dissolved at 1 wt % relative to the mixed solvent, had a viscosity of 4.4×10⁻³ Pa·s (=4.4 cp) at 25° C., the mixed solvent comprising these three solvents mixed at the above-mentioned ratio, each of the solvents having the viscosity stated above.

As stated above, the solute for forming the polymer material is dissolved in the mixed solvent comprising at least two kinds of solvents in the present invention. At least one kind of solvent in the mixed solvent comprises a high solubility with respect to the solute, i.e., a good solvent. It is preferred that such a good solvent be capable of dissolving 1 wt % or more solute. By using such a good solvent, it is possible to dissolve a solute that can sufficiently serve for formation of the organic film. In this embodiment, 1,3-dimethyl-2-imidazolidinone is a good solvent.

It is preferred that at least one kind of solvent in the mixed solvent comprise a solvent having a higher viscosity than the above-mentioned good solvent. Thus, it is possible to dissolve the solute even if a solvent having a high viscosity is used. Additionally, it is preferred to use a solvent having a viscosity of at least ten times the good solvent at room temperature (25° C.). In other words, a high viscosity solvent, which has a viscosity of at least ten times the good solvent, is used as a solvent for viscosity control. Thus, it is possible to easily use a solution, which can sufficiently dissolve a solute and has a viscosity appropriate for application. In this embodiment, cyclohexanol is used as an example of such a solvent having a high viscosity. By adjusting the mixing ratio of these solvents, it is possible to prepare a solvent having a viscosity appropriate for application. Thus, it is possible to uniformly apply the organic material and to prevent display quality from being deteriorated by non-uniformity in film thickness.

By adopting a method for applying a solution by using a mixed solvent comprising a good solvent and a solvent having a higher viscosity than the good solvent as stated above, it is possible to set the applied solution at a desired viscosity. Accordingly, it is possible to apply a solution having a viscosity appropriate for application and to reduce the occurrence of non-uniformity in film thickness of the organic material. When the above-mentioned 2-methyl-1-propanol is not used, i.e., when only two kinds of solvents of cyclohexanol and 1,3-dimethyl-2-imidazolidinone are used, it is preferred to adopt a different mixing ratio from the above-mentioned mixing ratio.

In the present invention, 2-methyl-1-propanol having a high volatility is used as another solvent in addition to the above-mentioned two kinds of solvents. This high volatile solvent completely volatilizes before arriving on the substrate when being sprayed by the spray applicator 50. In other words, when a solution containing a solute and the above-mentioned three kinds of solvents is applied by the spray applicator 50, 2-methyl-1-propanol completely volatilizes before the applied solution arrives on the substrate. Accordingly, the applied solution that arrives on the substrate is a solution comprising the solute and the two kinds of solvents of cyclohexanol and 1,3-dimethyl-2-imidazolidinone.

It is preferred that the solute have a density of from 3.5 to 11.0 wt % when the applied solution has arrived on the substrate. In this case, the solute density is set at a value of from 3.5 to 11.0 wt % with respect to the two kinds of mixed solvents of 1,3-dimethyl-2-imidazolidinone as a good solvent and cyclohexanol as a high viscosity solvent. Thus, it is possible to set the solute density at a value of from 3.5 to 11.0 wt % when the applied solution has arrived on the substrate. This is because 2-methyl-1-propanol as a volatile solvent completely volatilizes. It is also preferred to mix the solvents so that the solution that has arrived on the substrate has a viscosity of at least two times the solution before application.

Specifically, the solute is dissolved in a mixed solvent comprising two kinds of a good solvent and a high viscosity solvent so as to have a solute density of 3.5 wt %, for example. A desired amount of volatile solvent is additionally mixed in the mixed solvent with the solute dissolved therein. It is preferred that the solute density be 1 wt % or above relative to the total amount of the solvents. Although the order of mixing is that the solute is dissolved in the good solvent before mixing another solvent, the present invention is not limited to this order of mixing. When the solution containing these three kinds of mixed solvents is sprayed, the volatile solvent completely volatilizes and disappears after application before arrival on the substrate. Accordingly, the solute density is 3.5 wt % when the solution has arrived on the substrate. This causes a state wherein the solution having a solute density of 3.5 wt % adheres on the substrate. It should be noted that it is acceptable as long as the solute density is in the range stated above.

By taking the following steps, it is possible to determine whether a solvent having a high volatility has completely volatilized before the solvent arrives on the substrate, or not. Only 2-methyl-1-propanol is sprayed over the substrate by the spray applicator 50. In other words, only a volatile solvent, i.e., 2-methyl-1-propanol is filled into the spray applicator 50 and is sprayed from the spray nozzle 54. At that time, the volatile solvent is sprayed under the same conditions as the application conditions under which spraying is done in practice. In order to establish conditions close to actual process conditions, it is preferred that the volatile solvent be sprayed while scanning the spray nozzle 54. By visually checking whether 2-methyl-1-propanol has adhered on the substrate or not, it is possible to determine whether the volatile solvent has completely volatilized or not. In other words, if 2-methyl-1-propanol has not adhered to the substrate immediately after spraying, it is supposed that 2-methyl-1-propanol has completely volatilized before the solution has arrived on the substrate. On the other hand, if the volatile solvent has adhered to the substrate immediately after spraying, it is supposed that 2-methyl-1-propanol has not completely volatilized before the volatile solvent has arrived on the substrate. It is possible to easily make the determination since whether 2-methyl-1-propanol has adhered or not can be determined by checking whether the liquid has adhered to the substrate surface.

By taking the steps stated above, it is possible to check whether the volatile solvent has completely volatilized before the volatile solvent has arrived on the substrate. If 2-methyl-1-propanol adheres to the substrate because of incomplete volatilization, the stage 51 is moved in a vertical direction so as to increase the distance between the substrate 52 and the spray nozzle 54, for example. Then, the spraying step is performed again to check whether 2-methyl-1-propanol adheres to the substrate 52 or not. By repeating the same procedure with different distances, the distance between the substrate 52 and the spray nozzle 54, which can prevent the volatile solvent from arriving on the substrate 52, is found. By spraying the applied solution with a length longer than the found distance, it is possible to prevent the solvent having a high volatility from arriving the substrate.

When it is checked whether the volatile solvent arrives on a substrate, it is preferred to use as a verification substrate a glass substrate without a film formed thereon, instead of a panel substrate. This is because when the substrate has a resin film, such as an insulating film, formed on a surface thereof, it is difficult to check in some cases whether the volatile solvent arrives on the substrate or not. The checking process may be performed without the mask 53 being set in the spray applicator 50.

By finding the proper distance between the substrate and the spray nozzle as stated above, it is possible to easily find the proper distance between the substrate and the spray nozzle even when the volatile solvent material is changed. Thus, it is possible to easily change the volatile solvent according to a solute or another solvent. When 2-methyl-1-propanol was used as the volatile solvent, it was confirmed that the solvent has not arrived on the substrate when the distance between the substrate 52 and the spray nozzle 54 was set at, i.e., 80 mm. The solution containing the above-mentioned three kinds of solvents was applied, setting the distance between the substrate 52 and the spray nozzle 54 at the value thus found.

By using the solvent that has a high volatility and can completely volatilize during application as stated above, it is possible to increase the density of the solution that has arrived on the substrate. Thus, it is possible to the solution from flowing out along a separator. It is possible to uniformly apply the mixed solution by the spray applicator since the volatile solvent has not volatilized before application. Thus, it is possible to reduce the occurrence of degradation in display quality caused by non-uniformity in a film thickness.

It is possible to find the proper distance between the substrate and the spray nozzle 54 as stated above. However, in general, the spray applicator 50 has a predetermined distance range between a substrate and the spray nozzle, which allows the spray applicator to uniformly apply a solution. From this viewpoint, there is a possibility that when the distance between the substrate 52 and the spray nozzle 54 is longer than a predetermined value or above in order to cause a solvent to completely volatilize before arriving on the substrate, the solution fails to be uniformly applied to the substrate. For example, the distance between the substrate and the spray nozzle is longer than such a predetermined distance or longer, there is a possibility that non-uniformity in a film thickness is caused since the solution that has arrived on the substrate hops or since a deviation in application is caused, being affected by an airflow in the applicator.

In such a case, it is necessary to spray a solution, setting the distance at the predetermined value or below. From this viewpoint, it is preferred that a solvent having a certain value or more of volatility be used as the solvent that has a high volatility and is required to volatilize before arriving on the substrate. As the solvent that completely volatilizes before arriving on the substrate, it is appropriate to use a solvent that has a boiling point of 120° C. or below or a vapor pressure of about 400 Pa (=3 mmHg) or above at 25° C., for instance. Even if a solvent that partly volatilizes but does not completely volatilize before arriving on the substrate is used, it is possible to uniformly apply the solution in some cases.

As stated above, a solvent that has a high volatility and completely volatilizes before arriving on the substrate is added in the present invention. By addition of such a solvent, it is possible to obtain a mixed solvent that has a low viscosity when being sprayed from the spray applicator and has a high viscosity when arriving on the substrate. Thus, it is possible to prevent the solution from flowing out along a separator even when the temperature of the substrate is increased in a concentration and drying process. Accordingly, it is possible to reduce the occurrence of degradation in display quality caused by non-uniformity in a film thickness. The mixed solution has a lower viscosity is before application than after arriving on the substrate since the solvent having a high volatility in the mixed solution has not volatilized before application. Thus, it is possible to uniformly apply the solution by the spray applicator. As stated above, it is possible to improve display quality by adding, to the mixed solvent, a solvent that has a high volatility and volatilizes before arriving on the substrate.

Although an appropriate solution comprising three kinds of solvents is sprayed in the present invention, the present invention is not limited to such a mode. For example, the solution may comprise a good solvent and two kinds of solvents having a higher viscosity than the good solvent. In this regard, a mixed solvent comprising cyclohexanol and 1,3-dimethyl-2-imidazolidinone is used in the example stated above. By using such a mixed solvent, it is possible to obtain an applied solution having a high viscosity. N,N-dimethylacetamide may be used instead of 1,3-dimethyl-2-imidazolidinone.

When the applied solution comprises only two kinds of solvents of a good solvent and a solvent having a higher viscosity than the good solvent, it is preferred that the good solvent, which can dissolve a solute of 1 wt % or above, have a volume fraction of from 12.5 to 60%, and the solvent having a higher viscosity than the good solvent have a volume fraction of from 40 to 87.5%, for example. That is to say, it is preferred that the volume ratio of the good solvent to the solvent having a higher viscosity be from 1:7 to 3:2. In other words, it is preferred that the good solvent and the solvent having a higher viscosity be mixed so that the solvent having a higher viscosity have a volume of from ⅔ to 7 times the good solvent.

Or, the applied solution may comprise two kinds of solvents of a good solvent and a solvent that has a higher volatility than the good solvent and completely volatilize before arriving on the substrate. In this case, a mixed solvent comprising 1,3-dimethyl-2-imidazolidinone and 2-methyl-1-propanol is used in the example stated above. Since solvents having a high volatility have a low viscosity in general, there is a possibility that when only two solvents of a good solvent and a high volatile solvent are used, the viscosity of the entire solvent decreases. In this case, it is preferred to use three kinds of solvents of a good solvent, a high volatile solvent and a high viscosity solvent. It is also acceptable to use four kinds or more of solvents. It should be noted that the materials of the solvents stated above are typical examples and that the present invention is not limited to use the materials stated above.

It is preferred that the solute be dissolved in a solvent containing a good solvent before being mixed with all solvents. In the example stated above, it is preferred that the solute be dissolved in a solvent containing 1,3-dimethyl-2-imidazolidinone or 1,3-dimethyl-2-imidazolidinone before being mixed with the three kinds of solvents. Thus, it is possible to uniformly dissolve the solute. It should be noted that the solute may be dissolved in a solvent comprising all solvents mixed.

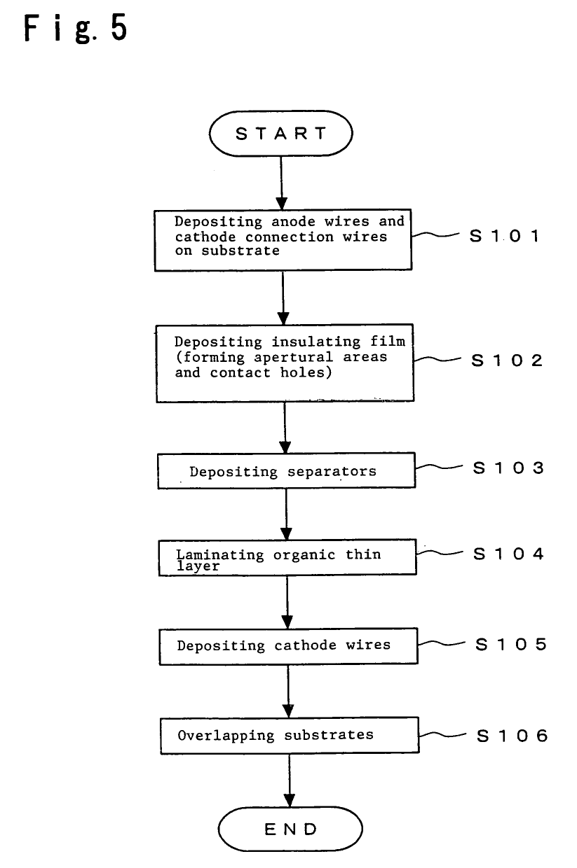

Now, the method for fabricating an organic EL display device, according to this embodiment will be described, referring to FIG. 5. FIG. 5 is a flowchart showing an example of the method for fabricating an organic EL display device, according to this embodiment. By the fabricating process shown in FIG. 5, the panel substrate shown in FIG. 1 is fabricated.

First, the anode wires and the cathode connection wires 21 are formed on the substrate 11 (step S101). The substrate 11 to be used comprises, e.g., a transparent substrate, such as a glass substrate. The anode wires 1 and the cathode connection wires 21 are formed by depositing an ITO film on the substrate 11 and etching the ITO film. The ITO film can be deposited on the entire glass substrate with good uniformity by sputtering or vapor deposition. The deposited ITO film is subjected to photolithography or etching to form an ITO pattern. The ITO pattern thus formed serves as anodes. A phenol novolac resin is used as the photoresist, and exposure and development are performed. Etching may be either wet etching and dry etching. For example, a mixed solution comprising hydrochloric acid and nitric acid may be used to subject the ITO film to patterning. The resist stripper to be used may comprise monoethanolamine for example.

The cathode connection wires 21 may be made of a metal material having a low resistivity, such Al or an Al alloy. For example, an Al film or the like is deposited by sputtering or vapor deposition after having subjected the ITO film as the anode wires 1 to patterning. Or, the anode wires 1 may be formed after the cathode connection wires 21 have been made. The cathode connection wires 21 may be formed by subjecting the Al film to patterning by photolithography or etching. Thus, it is possible to reduce the wire resistance of the cathode connection wires 21.

The cathode connection wires 21 may have a multi-layered structure comprising ITO and metal material. For example, a metal thin film comprising Mo or a Mo alloy and having a thickness of from 400 to 500 nm may be formed on an ITO film having 150 nm. Thus, it is possible to reduce the wire resistance and the contact resistance.

Next, the insulating film 22 is deposited on a surface of the substrate 11 with the anode wires 1 and the cathode connection wires 21 formed thereon (Step S102). For example, a photosensitive polyimide solution is applied by spin coating. It is sufficient that the insulating film 22 is applied so as to have a film thickness of, e.g., 0.7 μm. After the applied insulating film 22 as a layer is subjected to pattering in a photolithographic step, the insulating film is cured, and positions of the insulating film that serve as display pixels are removed to form the apertural areas 23. The intersection between an anode wire 1 and a cathode wire 5 formed in Step S105 stated later is the position where a display pixel is formed. At the same time, the contact holes 25, through each of which a cathode wire 5 and a cathode connection wire 21 are connected, are formed. For example, each of the apertural areas 23 may be formed so as to have dimensions of about 300 μm×300 μm.

Subsequently, the separators 10 are deposited so that the cathode wires 5 are disposed so as to be separated from one another on the insulating film (polyimide layer) 22 (Step S103). The separators 10 are disposed by applying a photosensitive resin, such as a novolac resin or an acrylic resin film as an upper layer on the insulating film 22. For example, such a photosensitive resin is spin-coated and is subjected to patterning in the photolithographic process, and then the patterned photosensitive resin is subjected to photoreaction to form the separators 10. It is desired that a negative photosensitive resin be used so as to provide the separators 10 with an inverted tapered structure.

When such a negative photosensitive resin is used and is irradiated by light from above, the photosensitive resin exhibits more insufficient photoreaction according to depth. As a result, the cross-section of the cured portion gradually decreases from an upper portion toward a lower potion when seen from above. This means that the separators have an inverted tapered structure. When the separators have such a structure, it is possible to separate the cathode wires 5 from one another since portions of the separators that are shaded from the viewpoint of a vapor deposition source when disposing the cathodes by vapor deposition are not affected by vapor deposition after the negative photosensitive resin is cured. Additionally, oxygen plasma or ultraviolet light may be irradiated for surface modification of the ITO film of each of the apertural areas 23. For example, the separators 10 may be set so as to have a height of 3.4 μm.

After that, the organic thin layer is laminated (Step S104). In this step, a desired solution is applied by the method for applying the organic material solution stated above. For example, in the case of using the mask spray method, first, a metal mask with apertural areas formed therein is mounted to a glass substrate. At that time, the metal mask is disposed so that an apertural area of the mask overlaps with an active area 24 to dispose an organic thin film. The mask is mounted to the glass substrate so as to be apart from the glass substrate by a certain distance, i.e., by a gap of, e.g., 60 μm. Then, the solution stated above is applied by the mask spray method.

Then, the organic material solution is condensed and dried to be cured, thereby forming the polymer buffer layer 41 comprising the organic thin film. The polymer buffer layer 41 is deposited as stated above. In the concentration and drying process, the organic material solution is preliminarily dried at a substrate temperature of 180° C. for 5 minutes, and then the organic material solution is finally baked at 240° C. for 10 minutes. Thus, the solvent is evaporated, and only the organic material as the solute adheres to the substrate.

Then, the hole injection layer 42 is deposited in a thickness of 40 nm on the polymer buffer layer 41, and the hole transportation layer 43 is deposited in a thickness of 10 nm on the hole injection layer. Additionally, the light emitting layer 44 is deposited in a thickness of 60 nm on the hole transportation layer. Subsequently, the electron transportation layer is deposited in a thickness of 30 nm on the light emitting layer, and the electron injection layer 45 is deposited in a thickness of 0.5 nm on the electron transportation layer. Thus, it is possible to form the organic light emitting layer shown in FIG. 2. The materials for forming the organic light emitting layer may be selected as desired. It should be noted that the structure stated above is an appropriate example, and that another structure is acceptable. In the present application, it is sufficient that at least one portion of the organic light emitting layer 40 is deposited by spray application.

After that, a metal material, such as aluminum, is vapor-deposited to dispose the cathode wires 5 in a film thickness of, e.g., 100 nm (Step S105). As a result, the aluminum film is separated in parts by the separators 10 so that a cathode wire 5 can be disposed between adjacent separators so as to intersect the anode wires 1.

The organic light emitting layer is disposed on the insulating film 22 and has contact with the anode wires 1 through the apertural areas 23. The organic light emitting layer has the cathode wires 5 disposed thereon. The portion of the organic light emitting layer that has contact with an anode wire 1 through the relevant apertural area 23 is caused to emit light by a current flowing between the cathode and the anode. In this embodiment, each of the cathode connection wires 21 has a two-layered structure comprising an ITO film and a metal film. Through the contact holes 25 disposed in a portion of the insulating film 22 outside the active are 24, the cathode wires 5 disposed in the active area 24 are electrically connected to the cathode connection wires 21, which extend outside the active area 24.

Now, a process for producing an opposed substrate for encapsulation, which is used to encapsulate the organic EL light emitting panel fabricated by the process stated above, will be described. First, a glass substrate is prepared, being independently from the panel substrate. The glass substrate is processed to form a moisture absorbent housing portion for housing a moisture absorbent. In order to form the moisture absorbent housing portion, a resist is applied on the glass substrate, and a portion of the substrate is exposed by exposure and development. The exposed portion is etched to be thinned, thereby forming the moisture absorbent housing portion.

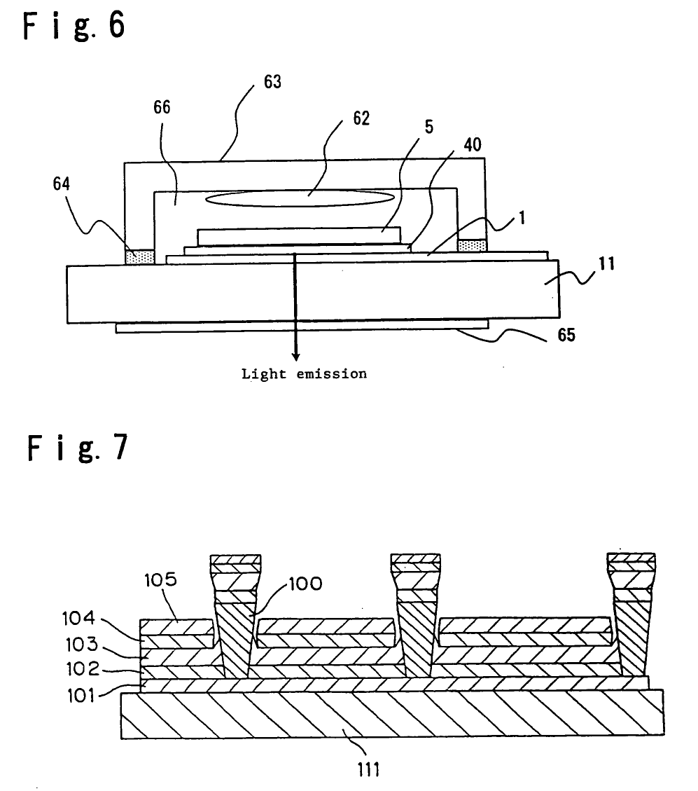

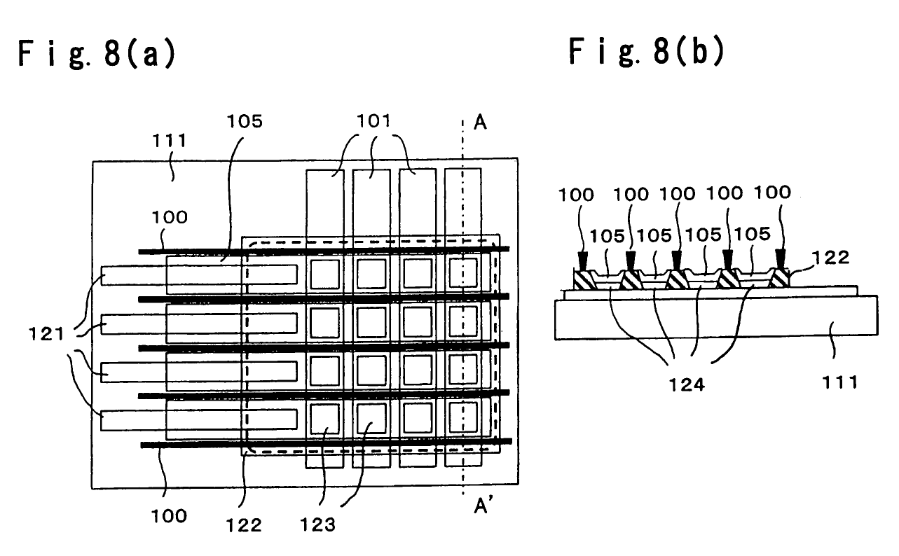

As shown in FIG. 6, a moisture absorbent 62, which comprises, e.g., calcium oxide, is put into the moisture absorbent housing portion 66, and then the panel substrate and the opposed substrate are overlapped and bonded together (Step S106). FIG. 6 is a cross-sectional view schematically showing the structure of an organic EL display device according to the present invention. Specifically, a dispenser is used to apply a sealing material 64 on a surface of the opposed substrate 63 with the moisture absorbent housing portion 66 formed thereon. The sealing material 64 may comprise, e.g., an ultraviolet curing epoxy resin. The sealing material 64 is applied to the entire outer periphery of the region of the opposed substrate, which confronts the organic EL panel. The two substrates are opposed so as to be mated together, and then both substrates are bonded together by irradiating ultraviolet light to cure the sealing material. After that, the bonded substrates are subjected to heat treatment for 1 hour in a clean oven at a temperature of, e.g., 80° C. in order to further promote the curing of the sealing material. As a result, the space between both substrates where the organic EL panel exists is isolated from the external space around the bonded substrates by the sealing material and the paired substrates. By disposing the moisture absorbent 62, it is possible to prevent the organic EL panel from being degraded by, e.g., moisture, which remains in or enters the encapsulated space.

Light is emitted from the organic thin layer 40 in the direction indicated by an arrow. An optical sheet 65 is affixed on a surface of the substrate 11 remote from the organic EL panel, i.e., an outgoing surface of the substrate 11. The optical sheet 65 comprises a polarizer and a ¼ wave plate and serves as an antireflective coating. The light from the organic thin layer is taken out toward the panel substrate with the optical sheet 65 disposed thereon.

Unnecessary portions in the vicinity of the outer periphery of the panel substrate are cut and eliminated, the anode wires 1 are connected to a signal electrode driver, and the cathode connection wires are connected to a scanning electrode driver. The panel substrate has an end portion formed with a terminal portion for connection with the respective wires. An anisotropic conductive film (ACF) is affixed on the terminal portion, and a TCP (Tape Carrier Package) with a driving circuit disposed thereon is connected to the terminal portion. Specifically, the ACF is preliminarily pressure-bonded to the terminal portion. Then, the TCP with the driving circuit incorporated therein is finally press-bonded to the terminal portion. Thus, the driving circuit is mounted. The organic EL display panel thus fabricated is mounted into a casing to complete an organic EL display device as a final product.

In accordance with the method for fabricating an organic EL display device as stated above, the organic material solution for forming the organic EL panel can be applied in a substantially constant film thickness. Accordingly, it is possible to reduce the occurrence of non-uniformity in a film thickness in the organic thin layer and to reduce the occurrence of non-uniformity in light emission of the respective display pixels when the driving the organic EL display device. The present invention is not limited to an organic EL display device having the separators 10.

Although explanation of the above-mentioned solvent has been made on a case wherein the solvent is used for forming the polymer buffer layer of the organic light emitting layer in the organic EL display device, the present invention is not limited to such a mode. In other words, the present invention is also applicable to a display device, which includes an organic film disposed by wet application. The present invention is also applicable to formation of an alignment layer in a liquid crystal display device or the separators in a plasma display panel (PDP), for example.

A panel substrate, which was fabricated by an applied solution using a volatile solvent as stated above, and a panel substrate, which was fabricated by an applied solution using no volatile solvent, were compared together. When the solution without 2-methyl-1-propanol added thereto was applied, the solution flowed out of the applied area, and non-uniformity in application was caused. On the other hand, by addition of 2-methyl-1-propanol, the solution was condensed when arriving on the substrate. Accordingly, the viscosity of the solution increased to decrease the liquid fluidity, restraining the solution from flowing out of the applied area. Accordingly, it was possible to obtain uniform film deposition without non-uniformity in application. By addition of 2-methyl-1-propanol, it was possible to obtain a uniform film thickness in the parameter range of the applicator at a film thickness that had not obtained by the conventional applied solution because of being outside the parameter range of the applicators.

The present application claims a priority under 35 U.S.C. §119 to Japanese patent application No. 2004-232781 filed Aug. 9, 2004. The entire disclosure of the Japanese patent application is incorporated herein by reference in its entirety.

1. A mixed solution for forming an organic layer for a display device, comprising:
a solute to form at least one portion of an organic layer;
a first solvent capable of dissolving said solute by 1 mass % or above; and
a second solvent having a higher viscosity than said first solvent.

2. The mixed solution according to claim 1, wherein said second solvent has a viscosity of 10 or more times said first solvent.

3. The mixed solution according to claim 1, wherein said second solvent has a volume of from ⅔ to 7 times said first solvent.

4. A mixed solution for forming an organic layer for a display device, comprising:
a solute to form at least one portion of an organic layer;
a first solvent capable of dissolving said solute by 1 mass % or above; and
a volatile solvent capable of completely volatilizing after spraying of the mixed solution toward a substrate for a display device and before arrival on the substrate.

5. The mixed solution according to claim 4, wherein the volatile solvent has a boiling point of 120° C. or below or a vapor pressure of 400 Pa or above at 25° C.

6. The mixed solution according to claim 4, further comprising a second solvent having a higher viscosity than said first solvent and said volatile solvent.

7. A method for fabricating a display device by wet-applying a solution, in which a solute forming a least one portion of an organic layer for the display device is dissolved; comprising steps of:
applying the solution to a substrate; and
drying the substrate and evaporating a solvent contained in the applied solution;
wherein the solution comprises:
a first solvent capable of dissolving said solute by 1 mass % or above; and
a second solvent having a higher viscosity than said first solvent.

8. The method according to claim 7, wherein said second solvent has a viscosity of 10 or more times said first solvent.

9. The method according to claim 7, wherein said second solvent has a volume of from ⅔ to 7 times the first solvent.

10. A method for fabricating a display device by spraying a solution, a solute forming a least one portion of an organic layer for the display device being dissolved in the solution; comprising the steps of:
spraying said solution toward a substrate; and
drying the substrate to evaporate a solvent contained in said sprayed solution;
wherein said applied solution comprises:
a first solvent capable of dissolving the solute by 1 mass % or above; and
a volatile solvent capable of completely volatilizing before said sprayed solution has been arrived on the substrate.

11. The method according to claim 10, wherein said volatile solvent has a boiling point of 120° C. or below or a vapor pressure of 400 Pa or above at 25° C.

12. The method according to claim 10, further comprising spraying a second solvent having a higher viscosity than said first solvent and said volatile solvent in the spraying step.

13. The method according to claim 10, further comprising of, before the spraying step, a step for confirming that the volatile solvent does not arrive on a confirmation substrate after only the volatile solvent is sprayed toward the confirmation substrate; and
spraying said solution under the same conditions as the confirmation step.

14. The method according to claim 10, further comprising of, before the spraying step, a step for spraying only the volatile solvent while changing a distance between a spray nozzle for spraying said solution and the confirmation substrate;
determining whether said volatile solvent sprayed toward the confirmation substrate arrives on the confirmation substrate or not, and
spraying the solution toward the substrate in the spraying step with a length between the spray nozzle and the substrate being set at at least a value that is determined to prevent the volatile solute from arriving on the confirmation substrate.
